(19) United States
(12) Patent Application Publication
(10) Pub. No.: US 2026/0327840 A1
(43) Pub. Date: Oct. 22, 2026

(54) PLATING METHOD AND PLATING APPARATUS

(71) Applicant: Tokyo Electron Limited, Tokyo (JP)

(72) Inventor: Takafumi NIWA, Koshi-shi, Kumamoto (JP)

(73) Assignee: Tokyo Electron Limited, Tokyo (JP)

(21) Appl. No.: 19/099,479

(22) PCT Filed: Aug. 2, 2023
(86) PCT No.: PCT/JP2023/028329

§ 371 Date: Jan. 29, 2025

(30) Foreign Application Priority Data
Aug. 3, 2022 (JP) 2022-124357

(51) Int. Cl. C25D 5/48

(52) U.S. Cl. CPC C25D 5/48

(57) ABSTRACT

A plating method includes supplying a plating liquid to a substrate to form a plating film on a surface of the substrate; supplying an oxidation accelerating liquid to the substrate to oxidize a metal residue on the surface of the substrate caused by the supplying of the plating liquid; intermediately drying the substrate after the supplying of the oxidation accelerating liquid to accelerate oxidation of the metal residue; supplying an alkaline chemical liquid to the substrate after the intermediately drying of the substrate to remove the oxidized metal residue; supplying a rinse liquid to the substrate after the supplying of the alkaline chemical liquid to remove the alkaline chemical liquid from the substrate; and finally drying the substrate after the supplying of the rinse liquid.

### TECHNICAL FIELD

The various aspects and embodiments described herein pertain generally to a plating method and a plating apparatus.

### BACKGROUND

In a manufacturing process for a semiconductor device, a wiring recess provided in a surface of a substrate such as a semiconductor wafer is filled with a wiring material by electroless plating. When the electroless plating is performed, metal residues are inevitably left. Patent Document 1 describes a technique in which post-cleaning of discharging a post-cleaning liquid to the substrate in the form of mist, pure water rinsing, and spin drying are performed after the electroless plating in order to remove the metal residues. An alkaline liquid containing TMAH with a pH of about 7 to 12, an organic acid containing a surfactant with a pH of 2 to 5, or pure water with a pH of 6 to 8 is used as the post-cleaning liquid.

### PRIOR ART DOCUMENT

Patent Document 1: Japanese Patent-Laid open Publication No. 2007-250915

### DISCLOSURE OF THE INVENTION

### Problems to be Solved by the Invention

Exemplary embodiments provide a technique capable of improving particle removing performance after plating.

### Means for Solving the Problems

In an exemplary embodiment, a plating method includes supplying a plating liquid to a substrate to form a plating film on a surface of the substrate; supplying an oxidation accelerating liquid to the substrate to oxidize a metal residue on the surface of the substrate caused by the supplying of the plating liquid; intermediately drying the substrate after the supplying of the oxidation accelerating liquid to accelerate oxidation of the metal residue; supplying an alkaline chemical liquid to the substrate after the intermediately drying of the substrate to remove the oxidized metal residue; supplying a rinse liquid to the substrate after the supplying of the alkaline chemical liquid to remove the alkaline chemical liquid from the substrate; and finally drying the substrate after the supplying of the rinse liquid.

### Effect of the Invention

According to the exemplary embodiment, it is possible to provide the technique capable of improving the particle removing performance after the plating.

### BRIEF DESCRIPTION OF THE DRAWINGS

FIG. 1 is a schematic transversal cross sectional view of a substrate processing system according to an exemplary embodiment of a substrate processing apparatus.

FIG. 2 is a schematic longitudinal cross sectional view illustrating a configuration example of an electroless plating device.

FIG. 3A to FIG. 3D are schematic diagrams for describing a metal residue removing mechanism.

### DETAILED DESCRIPTION

Specific exemplary embodiments of the present disclosure will be described with reference to the accompanying drawings. The following exemplary embodiments are merely examples of a substrate liquid processing method and a substrate liquid processing apparatus that embody the technical concept of the present disclosure, and do not limit the technical spirit of the present disclosure. Individual components in the drawing are shown in simplified forms. It should be noted that the sizes and shapes of the individual components in the drawings and the dimensional ratios therebetween may not necessarily match those of corresponding components in an actual apparatus, and they may not necessarily match between the drawings.

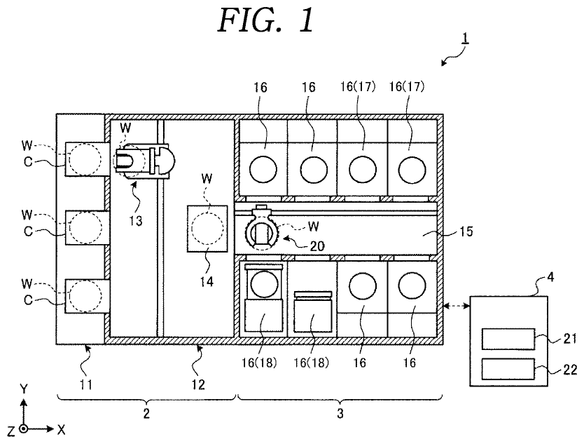

FIG. 1 is a diagram showing a schematic configuration example of a multi-layer wiring forming system 1. In FIG. 1, the X-axis, Y-axis, and Z-axis are perpendicular to each other. The X-axis and the Y-axis extend horizontally, and the positive Z-axis direction is a vertically upward direction.

The multi-layer wiring forming system (substrate liquid processing system) 1 shown in FIG. 1 includes a carry-in/out station 2, a processing station 3, and a control device 4.

The carry-in/out station 2 includes a carrier placement section 11 and a first transfer section 12. A plurality of carriers C is placed in the carrier placement section 11, and each carrier C supports one or more wafers W horizontally. The first transfer section 12 is provided adjacent to the carrier placement section 11, and includes a first substrate transfer device 13 and a delivery module 14.

The first substrate transfer device 13 is configured to transfer the wafer W between each carrier C and the delivery module 14. The first substrate transfer device 13 of the present exemplary embodiment is capable of moving the wafer W horizontally and vertically or rotating (pivoting) the wafer W around a vertical axis, while holding the wafer W. The delivery module 14 temporarily supports the wafer W received from the first substrate transfer device 13, or temporarily supports the wafer W to be transferred to the first substrate transfer device 13. The wafer W delivered from the delivery module 14 to the first substrate transfer device 13 is returned from the first substrate transfer device 13 back into the carrier C.

The processing station 3 is provided adjacent to the carry-in/out station 2 (particularly, the first transfer section 12) in the X-axis direction, and includes a second transfer section 15 and a plurality of processing devices 16.

The second transfer section 15 is equipped with a second substrate transfer device 20 configured to be movable along a transfer path. The second substrate transfer device 20 is capable of moving the wafer W horizontally and vertically or rotating (pivoting) the wafer W around a vertical axis. The second transfer section 15 transfers the wafer W received from the delivery module 14 to the required processing device 16, transfers the wafer W between the processing devices 16, or transfers the wafer W from the processing device 16 to the delivery module 14.

The plurality of processing devices 16 included in the processing station 3 are arranged on both sides of the transfer path (in the example shown in FIG. 1, the transfer path extending in the X-axis direction) of the second substrate transfer device 20. The layout and the number of these processing devices 16 are not limited to the example shown in FIG. 1, and the processing devices 16 may be arranged in any number and any layout.

A processing performed in each processing device 16 is not particularly limited basically, but at least one processing device 16 is configured as an electroless plating device (substrate liquid processing device) 17. The electroless plating device 17 performs electroless plating on the wafer W, as will be described later. Further, at least one processing device 16 may be configured as a reverse sputtering device 18 for use in a first modification example (FIG. 4A to FIG. 4E) to be described later.

As an example, the plurality of processing devices 16 belonging to the processing station 3 may include multiple electroless plating devices 17, multiple chemical mechanical polishing (CMP) processing devices, multiple heat treatment devices, and multiple cleaning devices. The CMP processing device performs a CMP processing on the wafer W. The heat treatment device performs a predetermined heat treatment on the wafer W. The cleaning device performs a cleaning processing on the wafer W, and includes, for example, a spin-clean type cleaner.

The control device 4 is, for example, a computer, and includes a controller 21 and a storage 22. The controller 21 includes a microcomputer having a central processing unit (CPU), a read only memory (ROM), a random access memory (RAM), input/output ports, and so forth, and various types of circuits. The CPU of the microcomputer reads and executes a program stored in the ROM to control the first transfer section 12, the second transfer section 15, and each processing device 16 (including the electroless plating device 17).

The program stored in the storage 22 of the control device 4 may have been recorded on a computer-readable recording medium, and may be installed from that recording medium into the storage 22. The computer-readable recording medium may be, by way of non-limiting example, a hard disk (HD), a flexible disk (FD), a compact disk (CD), a magnet optical disk (MO), and a memory card. The storage 22 may be implemented by, for example, a semiconductor memory device such as a RAM and a flash memory, a storage device such as a hard disk and an optical disk, or the like.

### Electroless Plating Device

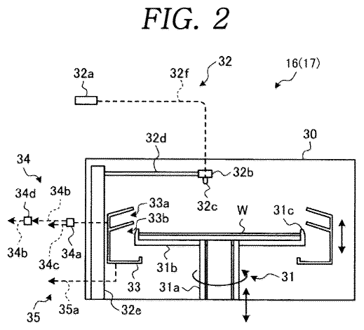

FIG. 2 is a diagram illustrating a configuration example of the electroless plating device (plating apparatus) 17. FIG. 2 shows a configuration of an inside of a housing 30 in a perspective manner.

The electroless plating device 17 shown in FIG. 2 is configured as a single-wafer processing device 16 configured to process wafers W one by one, and includes a housing 30, a substrate rotating/holding mechanism 31, a processing liquid supply mechanism 32, and a cup 33, all of which are at least partially disposed inside the housing 30.

The housing 30 has a non-illustrated openable/closable carry-in/out member. The wafer W transferred by the second substrate transfer device 20 (see FIG. 1) is carried into the housing 30 through the carry-in/out member in an open state, and is carried out from the inside of the housing 30 through the carry-in/out member in the open state. Meanwhile, while the wafer W is undergoing various processes (including electroless plating) in the housing 30 and while no process is being performed in the housing 30, the carry-in/out member is kept in a closed state, so an introduction of the exterior air into the housing 30 is restricted.

The substrate rotating/holding mechanism 31 is configured to hold the wafer W and rotate along with the wafer W. The substrate rotating/holding mechanism 31 has a hollow cylindrical rotation shaft 31a, a turntable 31b, a wafer chuck 31c, and a first rotational driver (not shown). The turntable 31b and the wafer chuck 31c constitute a substrate holder. The length of the rotation shaft 31a in an up-and-down direction inside the housing 30 is changed by a second elevating mechanism (not shown), which is driven under the control of the control device 4 (see FIG. 1). The turntable 31b is mounted to an upper end of the rotation shaft 31a. The wafer chuck 31c is provided on an outer peripheral portion of a top surface of the turntable 31b, and is configured to support the wafer W. As the length of the rotation shaft 31a in the up-and-down direction changes, the height positions (positions in the up-and-down direction) of the turntable 31b and the wafer chuck 31c change integrally. The first rotational driver applies a rotational power from a driving source such as a motor to the rotation shaft 31a, thus allowing the rotation shaft 31a, the turntable 31b, and the wafer chuck 31c to be rotated as one body.

The substrate rotating/holding mechanism 31 is operated under the control of the control device 4 (see FIG. 1). The rotation shaft 31a, the turntable 31b, and the wafer chuck 31c are rotated by the rotational power transferred from the first rotational driver, so that the wafer W supported by the wafer chuck 31c is rotated.

The processing liquid supply mechanism 32 is operated under the control of the control device 4 (see FIG. 1), and supplies a processing liquid (for example, an electroless plating liquid) to a surface of the wafer W held by the substrate rotating/holding mechanism 31. The processing liquid supply mechanism 32 in the present exemplary embodiment has a processing liquid supply 32a, a discharge head 32b, a discharge nozzle 32c, an arm 32d, a supporting shaft 32e, and a processing liquid supply path 32f.

The processing liquid supply 32a supplies the processing liquid to the discharge head 32b through the processing liquid supplying path 32f. The processing liquid supplied to the discharge head 32b is discharged from the discharge nozzle 32c mounted to the discharge head 32b, and is applied to, for example, a processing surface (top surface) of the wafer W. The discharge head 32b and the discharge nozzle 32c are mounted to a leading end of the arm 32d, and is moved as one body with the arm 32d. The arm 32d is supported by the supporting shaft 32e so as to be movable up and down, and is configured to be movable up and down inside the housing 30. Further, the arm 32d is configured to be rotated (pivoted) together with the supporting shaft 32e so as to be movable horizontally. The supporting shaft 32e is rotated around a central axis extending in the up-and-down direction by a non-illustrated second rotational driver.

The processing liquid supply mechanism 32 having the above-described configuration is capable of discharging the processing liquid from the discharge nozzle 32c placed at a required height position toward any required position on the processing surface (top surface) of the wafer W.

The cup 33 has two drain ports 33a and 33b disposed at different positions in the up-and-down, and receives the processing liquid scattered from the wafer W. The cup 33 is configured to be movable up and down by a second elevating mechanism (not shown) driven under the control of the control device 4 (see FIG. 1), and the height positions of the two drain ports 33a a d 33b are variable. The two drain ports 33a and 33b are connected to liquid draining mechanisms 34 and 35, respectively.

The liquid draining mechanisms 34 and 35 drain the processing liquid collected in the two drain ports 33a and 33b to the outside of the housing 30.

The liquid draining mechanism 34 has a recovery flow path 34b and a waste flow path 34c that are connected to the drain port 33a via a flow path switching device 34a. The flow path switching device 34a switches, between the recovery flow path 34b and the waste flow path 34c, a flow path into which the processing liquid from the drain port 33a can be introduced. The recovery flow path 34b is a flow path for reusing the processing liquid collected from the drain port 33a, and is provided with a cooling buffer 34d configured to cool the processing liquid. The waste flow path 34c is a flow path for discarding the processing liquid collected from the drain port 33a.

The liquid draining mechanism 35 has a waste flow path 35a connected to the other drain port 33b. The waste flow path 35a is a flow path for discarding the processing liquid collected from the drain port 33b.

The processing liquid supply 32a is configured to supply, as the processing liquid, the electroless plating liquid and other processing liquids (for example, an alkaline chemical liquid, an oxidation accelerating liquid, a rinse liquid, etc.) to the discharge head 32b and the discharge nozzle 32c. With this configuration, the processing liquid supply mechanism 32 is capable of performing a cleaning process using a cleaning liquid, a rinsing process using a rinse liquid, or another type of liquid processing on the wafer W before and after the application of the electroless plating liquid to the wafer W.

In addition, in FIG. 2, the processing liquid supply mechanism 32 is illustrated in a simplified manner, and the number of each of the processing liquid supply 32a, the processing liquid supply path 32f, the discharge head 32b, and the discharge nozzle 32c is shown to be one. However, the number and the configuration of the processing liquid supply 32a, the processing liquid supply path 32f, the discharge head 32b, and the discharge nozzle 32c are not limited thereto.

For example, the processing liquid supply 32a, the processing liquid supply path 32f, the discharge head 32b, and/or the discharge nozzle 32c may be provided in plural numbers. In this case, the processing liquid supply 32a, processing liquid supply path 32f, discharge head 32b, and/or discharge nozzle 32c for dedicated use may be provided for each of multiple types of processing liquids supplied from the processing liquid supply mechanism 32 to the wafer W. Alternatively, the processing liquid supply 32a, processing liquid supply path 32f, discharge head 32b, and/or discharge nozzle 32c for dedicated use may be provided only for one or more specific types of processing liquids. In this case, the processing liquid supply 32a, the processing liquid supply path 32f, the discharge head 32b, and/or the discharge nozzle 32c are shared for the other types of processing liquids.

Next, a processing on the wafer W in the electroless plating device will be explained. The wafer W with a recess formed therein is subjected to an appropriate pre-treatment as required. The pre-treatment referred to here includes any of various known treatments that can be performed before the plating when required, such as a silane coupling treatment, a seed layer forming treatment, and so forth.

### Electroless Plating Process

Thereafter, while rotating the wafer W held by the substrate rotating/holding mechanism 31 around the vertical axis, a plating liquid of, e.g., about 80 °C is discharged from the discharge nozzle 32c configured to discharge the plating liquid to a central portion of the wafer W. The plating liquid flows on the surface of the wafer W while being diffused toward a peripheral portion thereof so as to cover the entire surface of the wafer W. As a result, a plating layer is formed on the surface of the wafer W (for example, in a bottom-up manner from a bottom of a recess of a pattern) by the electroless plating. The portion where the plating layer is formed depends on the surface state of the wafer W after being subjected to the pre-treatment.

### Alkaline Chemical Liquid Supplying Process

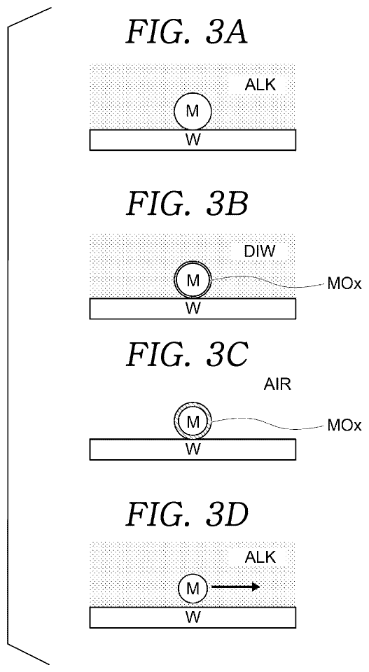

Next, while carrying on the rotation of the wafer W, the supply of the plating liquid is stopped, and an alkaline chemical liquid (ALK) is supplied to the central portion of the wafer W from the discharge nozzle 32c configured to discharge the alkaline chemical liquid. By way of non-limiting example, DIW mixed with tetramethylammonium hydroxide (TMAH) as a pH adjuster to have a pH of about 8 to about 14 may be used as the alkaline chemical liquid. As a result, the plating liquid and a reaction product remaining on the surface of the wafer W are removed. At this time, a metal residue M in the form of a particle, for example, is attached to the surface of the wafer W or a surface of the plating layer, as illustrated in FIG. 3A.

### Oxidation Accelerating Liquid Supplying Process

Subsequently, while keeping on rotating the wafer W, the supply of the alkaline chemical liquid is stopped, and an oxidation accelerating liquid is supplied to the central portion of the wafer W from the discharge nozzle 32c configured to discharge the oxidation accelerating liquid. By way of non-limiting example, DIW (pure water) or hydrogen peroxide mixed with tetramethylammonium hydroxide (TMAH) as a pH adjuster to have a pH of about 6 to about 7 may be used as the oxidation accelerating liquid. The oxidation accelerating liquid oxidizes a surface of the metal residue M left on the surface of the wafer W (formation of MOx (see FIG. 3B)), and the alkaline chemical liquid remaining on the surface of the wafer W is removed.

### Intermediate Drying Process

Then, while keeping on rotating the wafer W (desirably at an increased rotation speed of the wafer W), the supply of the oxidation accelerating liquid is stopped. That is, the wafer W is spin-dried (dried by being shaken off). As a result, the oxidation accelerating liquid remaining on the surface of the wafer W is removed from the surface by being scattered outwards from the wafer W by a centrifugal force, so the surface of the wafer W is exposed to the ambient air, which is an oxidation atmosphere around the wafer W. This causes a further progress of the oxidation of the metal residue remaining on the surface of the wafer W (growth of MOx (see FIG. 3C)).

### Alkaline Chemical Liquid Supplying Process

Next, while carrying on the rotation of the wafer W (at an original rotation speed of the wafer W), an alkaline chemical liquid is supplied to the central portion of the wafer W from the discharge nozzle 32c configured to discharge the alkaline chemical liquid. The alkaline chemical liquid used in this process may be the same as that used in the first alkaline chemical liquid supplying process. As a result, an oxidized portion MOx of the metal residue, especially the portion near the surface of the metal residue, dissolves in the alkaline chemical liquid, so that the metal residue is detached from the surface of the wafer W (see FIG. 3D). The detached metal residue is washed away from the surface of the wafer W by the alkaline chemical liquid.

### Rinsing Process

Next, while continuing to rotate the wafer W, the supply of the alkaline chemical liquid is stopped, and DIW is supplied as a rinse liquid to the central portion of the wafer W from the discharge nozzle 32c configured to discharge the oxidation accelerating liquid. That is, the wafer W is subjected to a DIW rinsing treatment. As a result, the alkaline chemical liquid remaining on the surface of the wafer W is removed.

### Final Drying Process

Next, while keeping on rotating the wafer W (desirable at an increased rotation speed of the wafer W), the supply of the rinse liquid is stopped. That is, the wafer W is spin-dried (dried by being shaken). As a result, the rinse liquid remaining on the surface of the wafer W is removed from the surface of the wafer W by being scattered outwards from the wafer W by a centrifugal force, and the surface of the wafer W is dried, which ends the plating process on the single sheet of wafer W.

The above-described exemplary embodiment may be modified as follows.

In the plating process including the above-described series of processes, the first alkaline chemical liquid supplying process may not be performed, and the oxidation accelerating liquid supplying process may be performed after the plating process. This is because the effect of removing the metal residue by the alkaline chemical liquid is enhanced after the surface of the metal residue is oxidized to a certain extent. However, by adjusting a zeta potential through the first alkaline chemical liquid supplying process, it may be possible to suppress particulate matters floating in the plating liquid at the end of the plating process (which still exists in an early stage of the alkaline chemical liquid supplying process) from adhering to the wafer W. Depending on how much effect of adjusting the zeta potential would be expected, it may be decided whether or not to perform the first alkaline chemical liquid supplying process.

After the first alkaline chemical liquid supplying process (after the plating process if the first alkaline chemical liquid supplying process is skipped), a process set consisting of the oxidation accelerating liquid supplying process, the intermediate drying process, and the alkaline chemical liquid supplying process may be repeated multiple times, and, then, the rinsing process and the final drying process may be performed. By repeating the oxidation and alkaline treatments, the metal residues that are difficult to remove can also be removed.

In the exemplary embodiment, all the processes other than the plating process are performed under the room temperature. However, the present disclosure is not limited thereto.

The intermediate drying process may be performed while blowing air to the surface of the wafer W being rotated.

Instead of the drying by the shaking-off, the intermediate drying process may be performed by scanning the surface of the wafer W with a discharge nozzle such as an air knife configured to discharge air in a band shape. The final drying process may also be performed in the same manner as the intermediate drying process.

### Experiment 1

Results of experiments confirming the effect of the exemplary embodiment will be explained below. Four processing conditions are set, and two sheets of wafers W are processed for each of the processing conditions.
Processing condition 1: electroless Cu plating process→DIW rinsing process→spin drying process
Processing condition 2: electroless Cu plating process→alkaline chemical liquid supplying process (15 sec)→DIW rinsing process (15 sec)→spin drying process
Processing condition 3: electroless Cu plating process→alkaline chemical liquid supplying process (90 sec)→DIW rinsing process (15 sec)→spin drying process
Processing condition 4: electroless Cu plating process >alkaline chemical liquid supplying process (15 sec)→┌DIW rinsing process (15 seconds)→spin drying process (intermediate drying process)→alkaline chemical liquid supplying process (15 seconds)┘×6 times→DIW rinsing process (15 seconds)→spin drying process (final drying process)

The number of particles with a size equal or larger than 60 nm remaining on the surface of the wafer W after the processing is found to be follows (N is an average of the particles on the two sheets of wafers W).
Processing condition 1: 922
Processing condition 2: 622
Processing condition 3: 331
Processing condition 4: 153

As can be seen from the above, the number of the particles can be significantly reduced by repeating the cycle of the DIW rinsing process (15 seconds)→spin drying process→alkaline chemical liquid treatment (15 seconds).

### Experiment 2

Four different processing conditions are set for a test piece with a Cu film formed on a surface thereof by PVD, and a decrement in the thickness of the Cu film after being subjected to the processing is examined for each of the processing conditions.
Processing condition 1: DIW rinsing process→spin drying process
Processing condition 2: alkaline chemical liquid supplying process (15 sec)→DIW rinsing process (15 sec)→spin drying process
Processing condition 3: alkaline chemical liquid supplying process (90 sec)→DIW rinsing process (15 sec)→spin drying process
Processing condition 4: alkaline chemical liquid supplying process (15 sec)→┌DIW rinsing process (15 seconds)→spin drying process (intermediate drying process)→alkaline chemical liquid supplying process (15 seconds)┘×6 times→DIW rinsing process (15 sec)→spin drying process (final drying process).

Results of this experiment are as follows.
Processing condition 1: ±0 (reference value)
Processing condition 2: −0.31 nm
Processing condition 3: −1.04 nm
Processing condition 4: −1.86 nm

As can be seen from the above, by oxidizing the surface of the Cu film through the DIW rinsing and the spin drying, the surface of the Cu film can be largely scraped off by the treatment with the alkaline chemical liquid. That is, by performing the treatment with the alkaline chemical liquid after performing the DIW rinsing and the spin drying, the metal residue originated from the Cu plating can be efficiently removed.

Also, as can be seen from Processing condition 4 of Experiment 2 described above, the thickness of the surface oxide layer formed by performing one rinsing process (DIW rinsing process) and one intermediate drying process is about 0.3 nm. As for the oxidizing property of the processing fluid (here, pure water in which oxygen in the air is dissolved after being discharged) to which the surface of the wafer W is exposed in the rinsing process and the processing fluid (here, air) to which the surface of the wafer W is exposed in the intermediate drying process, it is sufficient to form the surface oxide layer of this thickness. If the processing fluid having excessively high oxidizing property is used, the excessive damage will be caused to the plating layer.

The plating layer formed by the plating process is, for example, the Cu plating layer. However, the material of the plating layer is not limited to Cu, and any of various metals that can be oxidized by a fluid having relatively low oxidizing property, such as DIW and air, to form an oxide, and that can be easily dissolved by an alkaline chemical liquid, may be used. Examples of such metals include Co, Ru, Mo, and Ni.

Here, it should be noted that the above-described exemplary embodiments are illustrative in all aspects and are not anyway limiting. The above-described exemplary embodiments may be omitted, replaced and modified in various ways without departing from the scope and the spirit of claims.

The substrate as a processing target is not limited to the semiconductor wafer, and may be any of various types of substrates for use in the field of semiconductor device manufacture, such as a glass substrate, a ceramic substrate, and so forth.

1. A plating method, comprising:
supplying a plating liquid to a substrate to form a plating film on a surface of the substrate;
supplying an oxidation accelerating liquid to the substrate to oxidize a metal residue on the surface of the substrate caused by the supplying of the plating liquid;
intermediately drying the substrate after the supplying of the oxidation accelerating liquid to accelerate oxidation of the metal residue;
supplying an alkaline chemical liquid to the substrate after the intermediately drying of the substrate to remove the oxidized metal residue;
supplying a rinse liquid to the substrate after the supplying of the alkaline chemical liquid to remove the alkaline chemical liquid from the substrate; and
finally drying the substrate after the supplying of the rinse liquid.

2. The plating method of claim 1,
wherein the supplying of the oxidation accelerating liquid, the intermediately drying of the substrate, and the supplying of the alkaline chemical liquid are performed at least twice in this order between the supplying of the plating liquid and the supplying of the rinse liquid.

3. The plating method of claim 1,
wherein the oxidation accelerating liquid is pure water.

4. The plating method of claim 1,
wherein the oxidation accelerating liquid is a mixed solution of hydrogen peroxide and an alkaline pH adjuster.

5. The plating method of claim 1,
wherein the intermediately drying of the substrate is performed by spin drying.

6. The plating method of claim 1,
wherein air is blown to the surface of the substrate when the intermediately drying of the substrate is being performed.

7. The plating method of claim 1, further comprising:
supplying an alkaline chemical liquid to the substrate after the supplying of the plating liquid and before the supplying of the oxidation accelerating liquid.

8. A plating apparatus, comprising:
a substrate holder configured to hold a substrate;
a processing liquid supply mechanism configured to supply a plating liquid, the plating liquid being configured to perform a plating process on the substrate held by the substrate holder; and
a controller configured to control an operation of the plating apparatus to perform a plating method as claimed in claim 1.

9. The plating apparatus of claim 8, further comprising a substrate rotating/holding mechanism for holding the substrate around a vertical axis.

10. The plating apparatus of claim 9, wherein the processing liquid supply mechanism configured to supply the plating liquid to a central portion of the substrate while the substrate is rotated by the substrate rotating/holding mechanism to cause the plating liquid to flow on the surface of the substrate while being diffused toward a peripheral portion of the substrate to cover an entire surface of the substrate with the plating liquid.

11. The plating apparatus of claim 9, wherein the substrate rotating/holding mechanism includes:
a hollow cylindrical rotation shaft;
a turntable mounted to an upper end of the hollow cylindrical rotation shaft; and
the substrate holder, wherein the substrate holder is a wafer chuck provided on an outer peripheral portion of a top surface of the turntable.

12. The plating apparatus of claim 11, further comprising a cup surrounding the substrate rotating/holding mechanism.

13. The plating apparatus of claim 12, wherein the cup includes two drain ports, and
the two drain ports are configured to drain the plating liquid to outside of the plating apparatus.

14. The plating method of claim 1, wherein the supplying the plating liquid to the substrate is performed while rotating, by a substrate rotating/holding mechanism, the substrate around a vertical axis.

15. The plating method of claim 14, wherein the plating liquid is supplied to a central portion of the substrate while the substrate is rotated by the substrate rotating/holding mechanism to cause the plating liquid to flow on the surface of the substrate while being diffused toward a peripheral portion of the substrate to cover an entire surface of the substrate with the plating liquid.

16. The plating method of claim 14, wherein the supplying of the oxidation accelerating liquid, the intermediately drying of the substrate, the supplying of the alkaline chemical liquid and the supplying the rinse liquid are performed while the substrate is rotated by the substrate rotating/holding mechanism.

17. The plating method of claim 1, wherein the intermediately drying of the substrate is being performed while rotating, by a substrate rotating/holding mechanism, the substrate around a vertical axis, and
air is blown to the surface of the substrate when the intermediately drying of the substrate is being performed.

18. The plating method of claim 14, wherein the substrate rotating/holding mechanism includes:
a hollow cylindrical rotation shaft;
a turntable mounted to an upper end of the hollow cylindrical rotation shaft; and
a wafer chuck provided on an outer peripheral portion of a top surface of the turntable, the wafer chuck supports the substrate.

19. The plating method of claim 18, further comprising a cup surrounding the substrate rotating/holding mechanism.

20. The plating method of claim 19, wherein the cup includes two drain ports, and
the two drain ports are configured to drain the plating liquid to outside.
